(19) United States
(12) Patent Application Publication
(10) Pub. No.: US 2013/0186453 A1
(43) Pub. Date: Jul. 25, 2013

(54) MITIGATING PHOTOVOLTAIC MODULE STRESS DAMAGE THROUGH CELL ISOLATION

(71) Applicant: FIRST SOLAR, INC, Perrysburg, OH (US)

(72) Inventors: Zhibo Zhao, Novi, MI (US); David Hwang, Perrysburg, OH (US); Dmitriy Marinskiy, Tampa, FL (US); Zhengjue Zhang, Perrysburg, OH (US); Chungho Lee, San Jose, CA (US); Muhammad Khatri, Perrysburg, OH (US); Benyamin Buller, Silvania, OH (US)

(73) Assignee: FIRST SOLAR, INC, Perrysburg, OH (US)

(21) Appl. No.: 13/713,757

(22) Filed: Dec. 13, 2012

Related U.S. Application Data
(60) Provisional application No. 61/570,043, filed on Dec. 13, 2011.

(51) Int. Cl. H01L 31/042; H01L 31/18

(52) U.S. Cl. CPC H01L 31/042; H01L 31/18
USPC 136/251; 438/80

(57) ABSTRACT

Described herein is a photovoltaic module and method of manufacturing a photovoltaic module to isolate potentially stress-damaged portions of cells from non-stress-damaged portions thereof. The module has a plurality of columnar photovoltaic cells, and at least one isolation scribe at a first edge of an active area of the photovoltaic module and extending across a photovoltaic cell in a direction perpendicular to a length of the columnar cells, where the at least one isolation scribe is deep enough to electrically isolate portions of the photovoltaic cell on opposite sides of the at least one isolation scribe.

### CLAIM OF PRIORITY

This application claims priority under 35 U.S.C. §119(e) to U.S. Provisional Patent Application Ser. No. 61/570,043 filed on Dec. 13, 2011, which is hereby incorporated by reference in its entirety herein.

### FIELD OF THE INVENTION

Disclosed embodiments relate to the field of photovoltaic (PV) power generation systems, and more particularly to a photovoltaic module and manufacturing method thereof.

### BACKGROUND

Photovoltaic modules convert the energy of sunlight directly into electricity by the photovoltaic effect. Photovoltaic modules can include a plurality of photovoltaic cells or devices. As one example, a photovoltaic module can include multiple layers created on a transparent substrate (or superstrate), such as a glass. For example, a photovoltaic module can include a transparent conductive oxide (TCO) layer, a buffer layer, and semiconductor layers formed in a stack on a substrate. The semiconductor layers can include a semiconductor window layer, such as a zinc oxide layer or a cadmium sulfide layer, formed on the buffer layer and a semiconductor absorber layer, such as a cadmium telluride layer, formed on the semiconductor window layer. The semiconductor window layer can allow the penetration of solar radiation to the absorber layer, which converts solar energy to electricity. A conductor may be deposited adjacent to the semiconductor absorber layer to serve as a back contact for the module. To complete the module, a back support, typically formed of glass, is provided over the back contact.

A long field operation lifespan, without failure, of over about 20 years is desirable for PV modules. Generally, in the field, four external clamps 100, shown in FIG. 1, are used to hold a PV module 10 to an underlying supporting structure. During normal operation, a high voltage differential may occur between cells within the PV module, which may have voltages as high as 1000V, and the external clamps 100, which are at OV. This high voltage differential is believed to cause sodium (Na) diffusion from the glass substrate to other active areas within the module, which may cause various stress defects in the module near the area of the clamps 100. For example, too much sodium can build up at the interface of layers and can push apart the interfaces, which causes structural damage. Additionally, sodium can diffuse into the other layers and cause current leakage. Although the region with structural damage is typically highly localized within a small area, it may cause much larger areas of the module to be affected electrically.

FIG. 2 illustrates a conventional photovoltaic module 10 with a peripheral edge area 200, where no photovoltaic cells are present, and an area of columnar series connected cells 300. A conventional photovoltaic module 10, like that shown in FIG. 2, can exhibit performance issues related to stress defects. If any portion of a columnar cell 300 is damaged by stress near the location of a clamp 100, for example, the damage can spread to other parts of the cell more spatially removed from clamps 100. A method and apparatus are accordingly desired, to mitigate the effect of stress defects in areas of the module held to a supporting structure by external clamps 100.

### BRIEF DESCRIPTION OF THE DRAWINGS

FIG. 1 illustrates a photovoltaic module set-up.

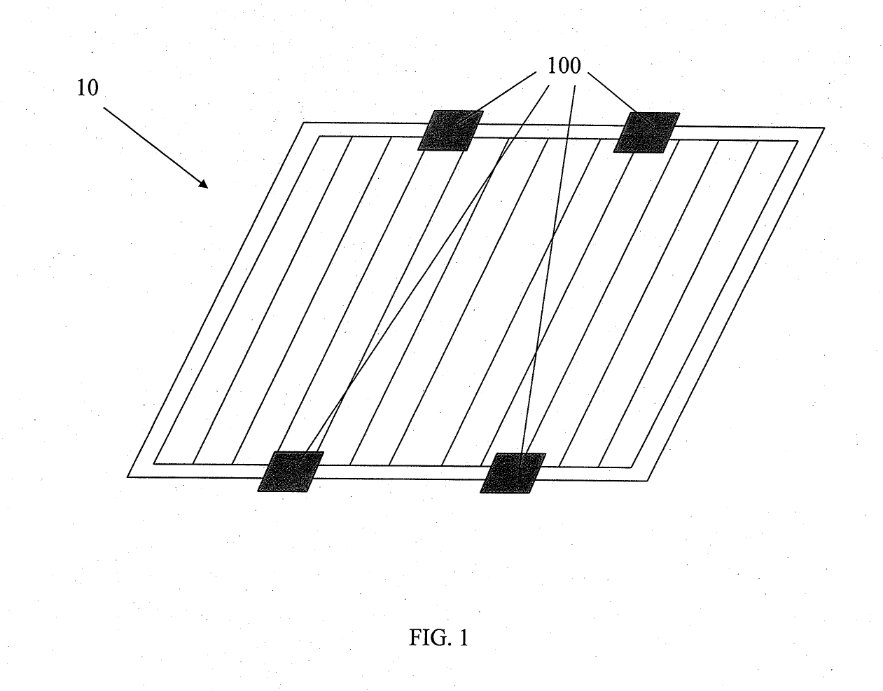

FIG. 2 illustrates a conventional photovoltaic module.

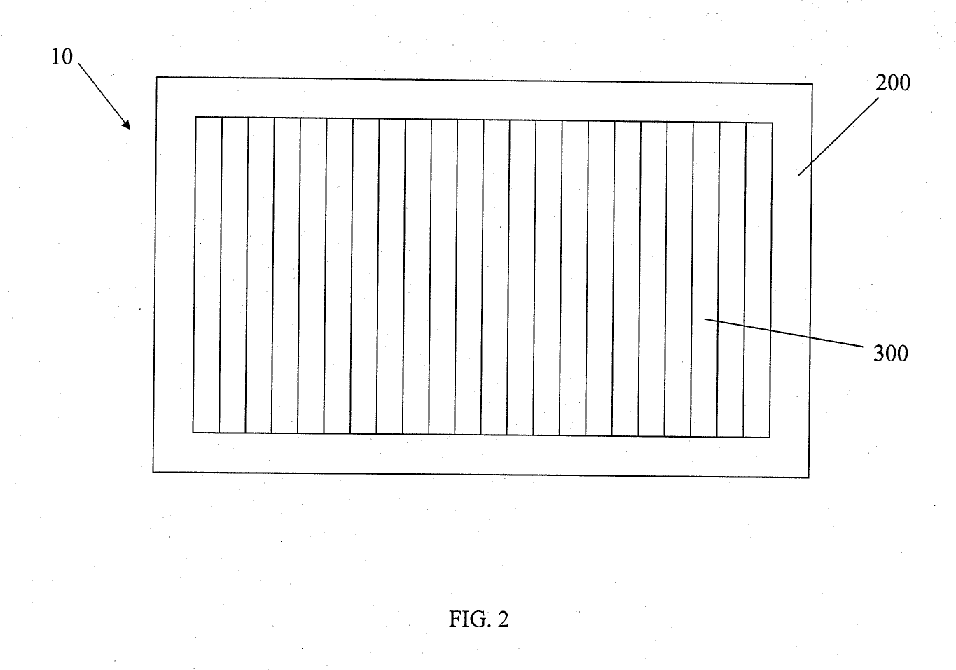

FIG. 3 is a schematic of a conventional photovoltaic module with localized structural damages caused by stressing.

FIG. 4 illustrates a photovoltaic module according to a first embodiment.

FIG. 5 is a schematic of a photovoltaic module according to a first embodiment with stress damage.

FIG. 6 illustrates a photovoltaic module according to a second embodiment.

FIG. 7 illustrates a photovoltaic module according to a third embodiment.

FIG. 8 illustrates a photovoltaic module according to a fourth embodiment.

FIG. 9 illustrates a simulated current-voltage curve for a photovoltaic module before stress.

FIG. 10 illustrates a simulated current-voltage curve for a conventional photovoltaic module after stress.

FIG. 11 illustrates a simulated current-voltage curve for a photovoltaic module according to the first embodiment, after stress.

### DETAILED DESCRIPTION

In the following description, reference is made to the accompanying drawings, which form a part hereof, and in which is shown by way of illustration specific embodiments that may be practiced. It should be understood that like reference numbers represent like elements throughout the drawings. Embodiments are described in sufficient detail to enable those skilled in the art to make and use them, and it is to be understood that structural, material, electrical, and procedural changes may be made to the specific embodiments disclosed, only some of which are discussed in detail below.

Described herein is a photovoltaic module including isolation scribes, which isolate portions of cells that may be subject to stress defects from the rest of the module. The isolation scribes segregate stress-damaged portions of cells from healthy portions of the cells in an active area of a PV module, thus preventing damage from spreading to maximize the total undamaged, usable active area of the PV module. According to the embodiments described herein, the active area sacrificed by adding the isolation scribes is negligible because the isolation scribes only have a width of about 50 μm and the amount of active area that is sacrificed by adding the isolation scribes is only about 0.008% of the total active area (for a 2 ft×4 ft photovoltaic cell, for example). Thus, using isolation scribes according to the embodiments of the invention increases the overall efficiency of the PV module by segregating portions of cells, which may become damaged, from healthy portions of cells to keep the majority of the cells healthy and functional.

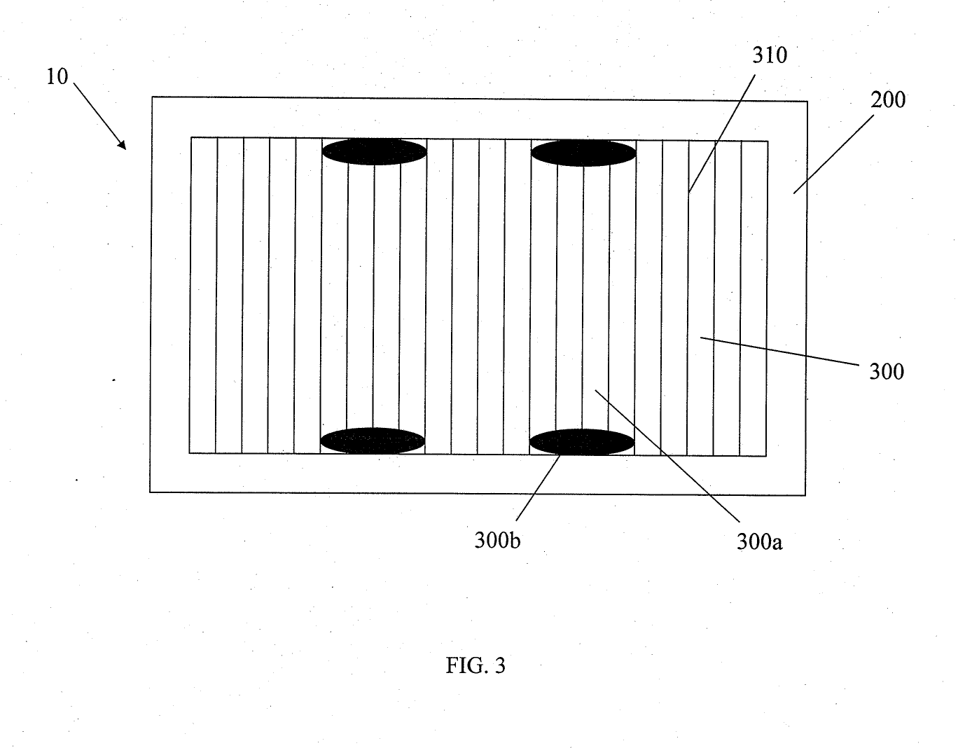

A photovoltaic module includes a set of columnar cells 300, as shown, for example, in FIG. 3, which are connected in series. A typical photovoltaic module is about 2 ft×4 ft and has around 118 columnar cells (each about 1 cm×2 ft). According to the design of a photovoltaic cell 300, localized damage within a cell affects the performance of the entire cell. In other words, local damage in a cell, e.g., at area 300b near the location of an external clamp 100, may cause electrical degradation of other parts of the cell, e.g., areas 300a, and may eventually cause degradation of the entire cell. It has been found that one of the most stressed areas for a cell during operation are near the clamps 100 that hold module 10 to a supporting structure in the field. Although the structural damage caused by high voltage biasing are generally confined near the clamp areas (such as shown by 300b), the associated degradation in electrical performance extends to much larger areas (such as shown by 300a). Embodiments described herein help mitigate stress damage in PV modules. The isolation scribes of the disclosed embodiments act to prevent the spread of detrimental effects from a damaged portion of a cell to the rest of cell.

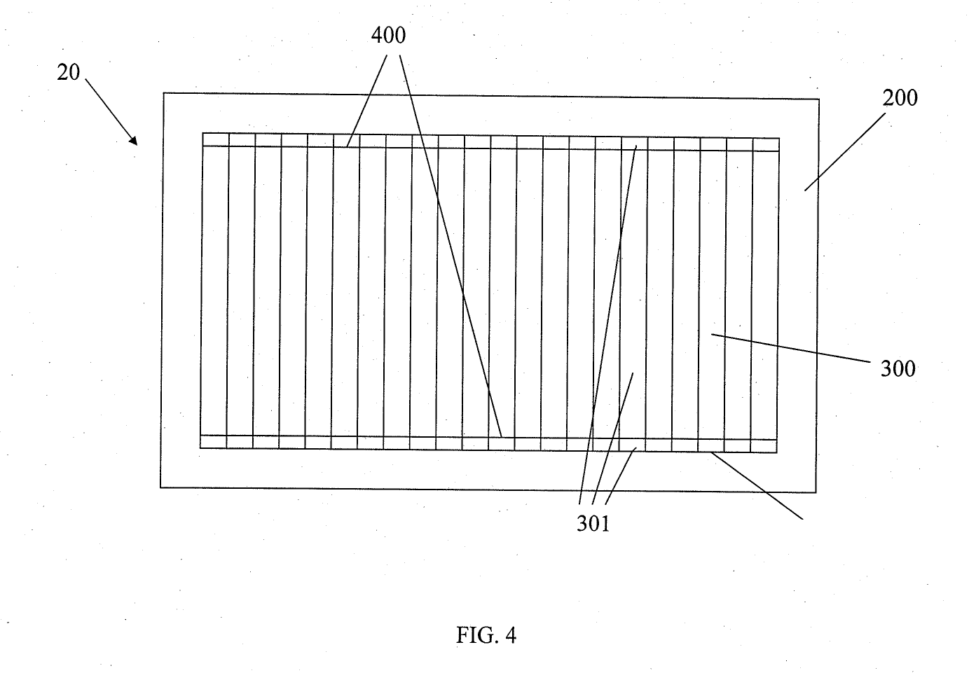

Referring to FIG. 4, a first embodiment is now described with reference to the manufacture of a photovoltaic module. Photovoltaic module 20 has edge area 200, where no photovoltaic cells (active area) are present, and columnar solar cells 300, connected in series. Isolation scribes 400 are formed at the top and bottom of photovoltaic module 20. The distance between the top and bottom edge areas 200 and isolation scribes 400 can be determined by the size of the stress-damaged area, which is also affected by clamp size. The distance from the isolation scribe 400 to the edge area 200 is between about 1 mm to about 4 cm. The isolation scribes 400 can be formed by laser, mechanical, and any other scribing methods. The scribe, or patterning, depth should be deep enough to produce an electrical isolation between areas of the cells 300 adjacent the edge area 200 of the module 20 and the remainder of the cells 300. It can be done by cutting through at least one of the following layers: a contact layer including TCO, and a semiconductor layer. After isolation scribes 400 are formed, the area between the isolation scribes 400 and the edge area 200 remains an active area (because the cells within that area are still electrically connected in series). For example in this embodiment, in any given columnar cell 300, once the isolation scribes 400 are made, the columnar cell 300 will then be made of two smaller columnar cells 301 (i.e., the cells in the area between the edge 300 and the top isolation scribe 400 and the cells in the area between the edge 300 and the bottom isolation scribe 400) and the columnar cell between the top and bottom isolation scribes 400. All three columnar cells will then be connected in parallel and all will remain a part of the active area. The only part of the columnar cell 300 that is not an active area is the area of the isolation scribes 400. Thus, the only area sacrificed by adding the isolation scribes is equal to the width of the isolation scribe itself (about 50 μm) multiplied by the length of the isolation scribe (in this case, the length of the module 20). In this way, the disclosed embodiments can segregate areas of the columnar cells 300 that are likely to be damaged during use of the PV module while only sacrificing a negligible amount of active area.

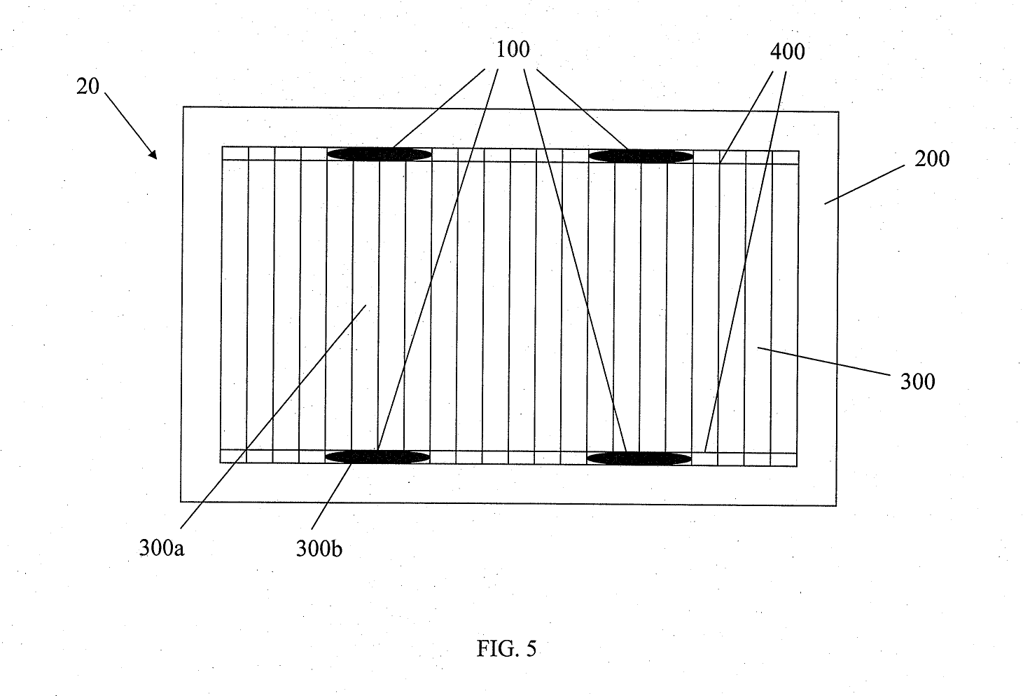

FIG. 5 is a schematic diagram of a stress-damaged photovoltaic module 20 manufactured according to the first embodiment. Stress-damaged areas 300b are located around where the clamps 100 will be located. Although the region with structural damage is typically highly localized within a small area, it may cause much larger areas of the module to be affected electrically. Photovoltaic module 20 is manufactured with isolation scribes 400, to isolate the cells in the stress-damaged areas 300b and to prevent them from affecting the cells in the remaining healthy areas 300a. For example, the isolation scribes 400 may prevent sodium (Na) diffusion from the glass substrate across the scribes to other active areas within the cell 300 and module 20. Additionally, the scribe lines isolate the damaged areas, so that current will continue to flow through the cells having the damaged areas, but not through the damaged areas themselves. In this way, the cells are shunted, and only the damaged areas are isolated, while the other regions of the cells are protected. Without the isolation scribes 400, the structural damage in the localized areas 300b could cause the degradation of much larger areas (e.g., such as shown by 300a).

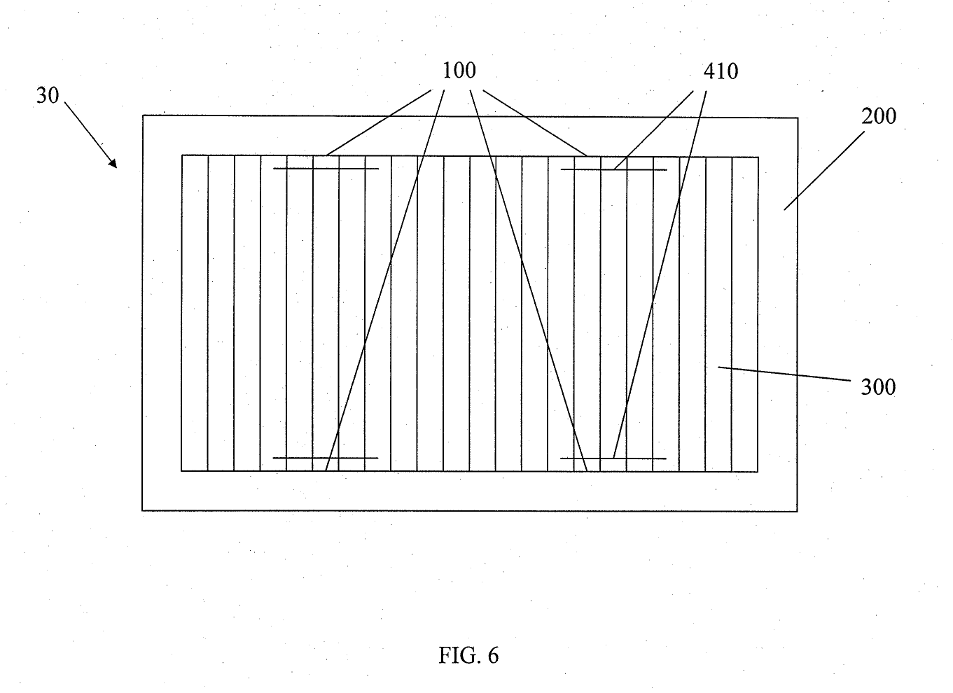

Referring to FIG. 6, a second embodiment is now described with reference to the manufacture of a photovoltaic module. Photovoltaic module 30 has edge area 200, where no photovoltaic cells (active area) are present, and columnar cells 300. In this embodiment, only the portions of the active area corresponding to locations where cells are likely to be damaged are scribed. Thus, in contrast to the first embodiment, isolation scribes 410 only isolate cells around clamp areas 100, which are the ones that are most likely to be damaged during operation of the module (e.g., areas 300b; FIG. 5). In this case, the length of isolation scribes 410 should be long enough to include at least one cell on either side of the areas 300b that is unlikely to be damaged. Clamps 100 are typically about 4 to 6 inches long. Preferably, the length of isolation scribes 410 should be longer than the length of clamps 100 by about ½ inch on either side. Thus, the scribes will be long enough to isolate the clamp areas even if the clamp 100 placement is offset during module installation. Again, the width of isolation scribes 410 is about 50 μm and the distance from the isolation scribes 410 to the edge area 200 is between about 1 mm to about 4 cm. This embodiment will minimize current crowding (i.e., a non-homogeneous distribution of current density) through the shunted cells by raising the resistance.

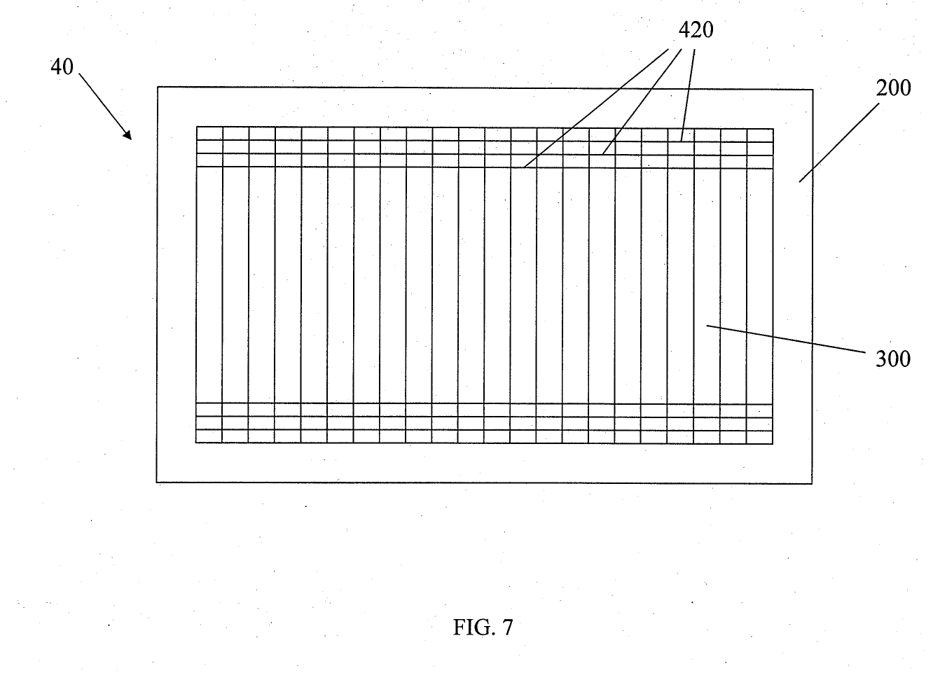

Referring to FIG. 7, a third embodiment is now described with reference to the manufacture of a photovoltaic module. Photovoltaic module 40 has edge area 200, where no photovoltaic cells (active area) are present, and columnar cells 300. According to this embodiment, multiple isolation scribes 420 are utilized. Thus, in contrast to the first and second embodiments, which each only have one isolation scribe 400, 410 on each side of the module, this embodiment uses multiple isolation scribes 420 on each side. Again, the width of isolation scribes 420 is about 50 μm and the distance from the isolation scribes 420 to the edge area 200 is between about 1 mm to about 4 cm. The distance between adjacent isolation scribes 420 may also be between about 1 mm to about 4 cm. Stress damage can spread and cover larger areas over time. Thus, to mitigate against stress damage spreading past the single scribe, this embodiment utilizes multiple isolation scribes in case any of the isolation scribes 420 are defective and are unable to achieve electrical isolation or if the stress damage occurs further from the module edge area 200 than is protected by a single scribe.

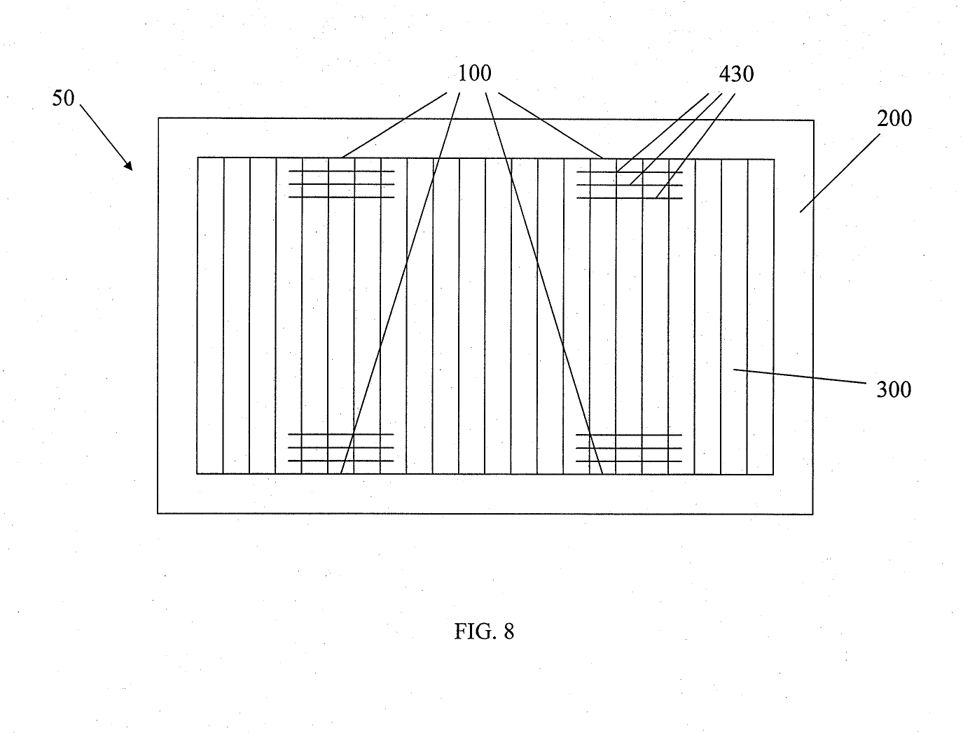

Referring to FIG. 8, a fourth embodiment is now described with reference to the manufacture of a photovoltaic module. Photovoltaic module 50 has edge area 200, where no photovoltaic cells (active area) are present, and columnar cells 300. This embodiment uses multiple isolation scribes 430 that only isolate the damaged areas 300b around clamp 100. The length of isolation scribes 430 should be longer than the damaged areas to include at least one healthy cell on either side of the damaged area 300b. Clamps 100 are typically about 4 to 6 inches long. Preferably, the length of isolation scribes 430 should be longer than the length of clamps 100 by about ½ inch on either side. Thus, the scribes will be long enough to allow for any offset of clamp 100 placement during module installation. Again, the width of isolation scribes 430 is about 50 μm and the distance from the isolation scribes 430 to the edge area 200 is between about 1 mm to about 4 cm. The distance between adjacent isolation scribes 430 may also be between about 1 mm to about 4 cm. Similar to the embodiment of FIG. 7, the embodiment of FIG. 8 utilizes multiple isolation scribes to ensure that the damaged area does not spread past the single isolation scribes.

Thus, according to the embodiments described herein, the isolation scribes isolate healthy portions of cells of a PV module from potentially stress-damaged portions of cells of the PV module. The potentially stress-damaged portions remain active areas in the overall circuit, but can lower the overall output of the photovoltaic module. The isolation scribes described herein, confine the potentially stress-damaged areas so that the stress damage does not spread or extend to healthy portions of the cell where they might cause a lower output of the photovoltaic module.

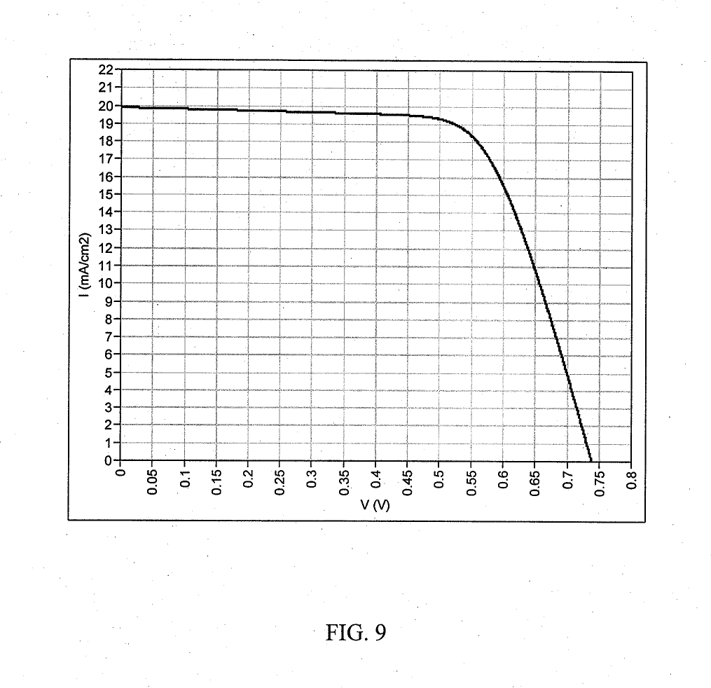

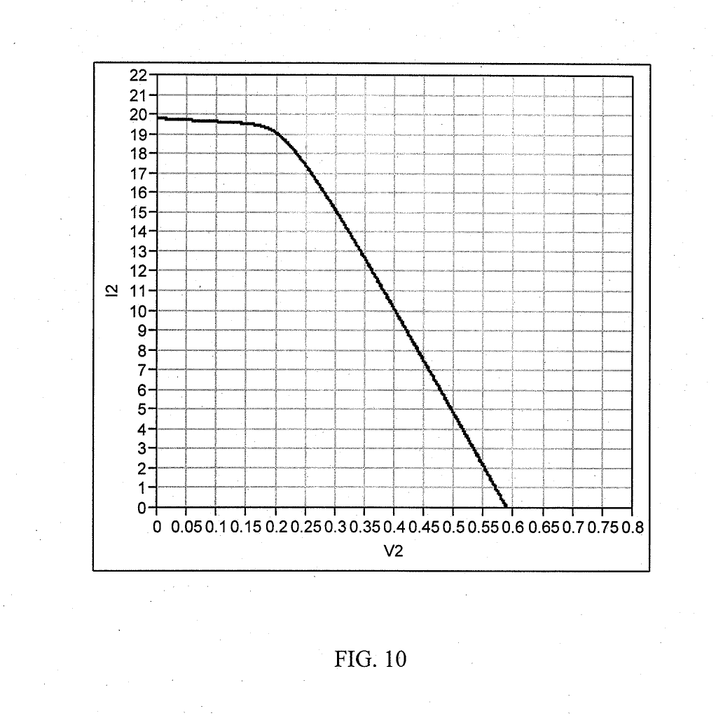

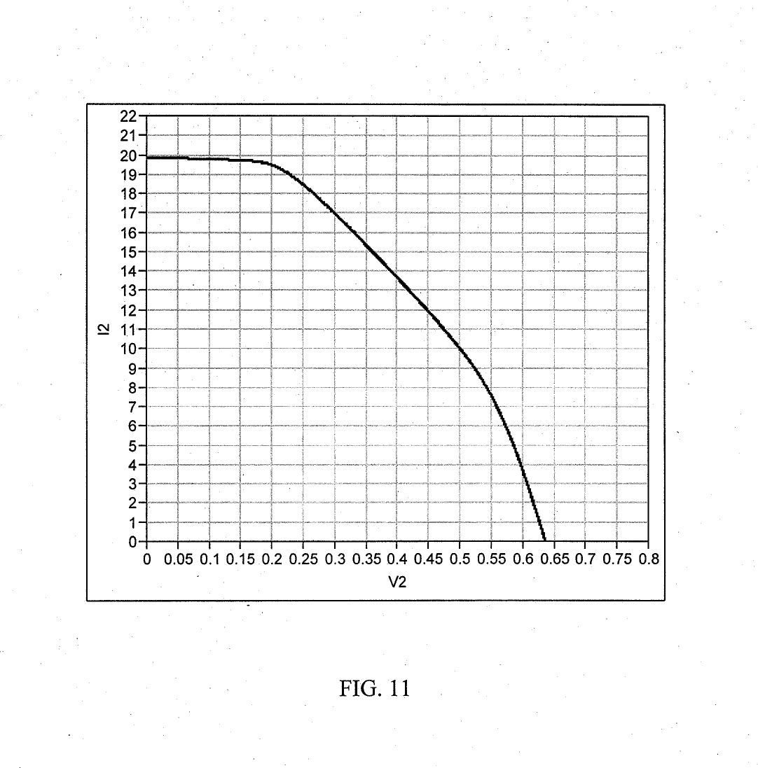

Referring to FIGS. 9 to 11, several current-voltage (I-V) curves are shown, which illustrate the beneficial effects on device performance of using isolation scribes to isolate damaged areas. FIG. 9 illustrates a simulated I-V curve for a photovoltaic module prior to any stress. According to the simulation, the fill factor (FF) is about 69.3. Fill factor is a parameter which, in conjunction with open-circuit voltage (V_{OC}) and short-circuit current (I_{SC}), determines the maximum power or energy yield from a photovoltaic module. The fill factor is defined as the ratio of the maximum power from the photovoltaic module to the product of V_{OC} and I_{SC}. Graphically, the fill factor is a measure of the “squareness” of the photovoltaic module, and is also the area of the largest rectangle that will fit under the I-V curve. FIG. 10 illustrates a simulated I-V curve for a conventional photovoltaic module (without isolation scribes) after stress damage. The fill factor is 39.9. FIG. 11 illustrates a simulated I-V curve for a photovoltaic module with isolation scribes according to the first embodiment described herein, after stress damage. As seen in FIG. 11, there is obvious V_{OC} and fill factor improvement compared to FIG. 10 with the conventional photovoltaic module.

While disclosed embodiments have been described in detail, it should be readily understood that the invention is not limited to the disclosed embodiments. Rather, the disclosed embodiments can be modified to incorporate any number of variations, alterations, substitutions or equivalent arrangements not heretofore described.

What is claimed as new and desired to be protected by Letters Patent of the United States is:

1. A photovoltaic module, comprising:
a plurality of columnar photovoltaic cells; and
at least one isolation scribe near a first edge of an active area of the photovoltaic module, which extends across at least one photovoltaic cell in a direction perpendicular to a length of the columnar cells, wherein the at least one isolation scribe is deep enough to achieve electric isolation between portions of the at least one photovoltaic cell on opposite sides of the at least one isolation scribe.

2. The photovoltaic module of claim 1, wherein the at least one isolation scribe is deep enough to scribe through any one of a contact metal layer, a semiconductor layer, or a transparent conductive oxide layer of the photovoltaic module

3. The photovoltaic module of claim 1, wherein the at least one isolation scribe is located about 1 mm to about 4 cm from the first edge of the active area.

4. The photovoltaic module of claim 3, wherein the at least one isolation scribe extends an entire length of the photovoltaic module.

5. The photovoltaic module of claim 1, wherein the at least one isolation scribe extends across the at least one photovoltaic cell at locations of the photovoltaic module where a clamp mounts the photovoltaic module to a supporting structure, and wherein the at least one isolation scribe further extends across at least one photovoltaic cell beyond each edge of the clamp.

6. The photovoltaic module of claim 5, wherein the at least one isolation scribe is about 5 inches to about 7 inches in length.

7. The photovoltaic module of claim 1, wherein the at least one isolation scribe has a width of about 50 μm.

8. The photovoltaic module of claim 1, further comprising at least a second isolation scribe spaced from and parallel to the at least one isolation scribe, wherein the at least a second isolation scribe is patterned to extend the same length as the at least one isolation scribe and is spaced about 1 mm to about 4 cm therefrom.

9. The photovoltaic module of claim 5, wherein a length of the at least one isolation scribe is longer than a length of the clamp that mounts the photovoltaic module to the supporting structure by at least one inch.

10. A method of forming a photovoltaic module, comprising the steps of:
forming a photovoltaic module with columnar cells; and
patterning at least one isolation scribe near a first edge of an active area of the photovoltaic module, which extends across at least one columnar cell in a direction perpendicular to a length of the columnar cells, wherein the at least one isolation scribe is deep enough to achieve electric isolation between portions of the at least one columnar cell on opposite sides of the at least one isolation scribe.

11. The method of claim 10, wherein the at least one isolation scribe is patterned about 1 mm to about 4 cm from the first edge of the active area.

12. The method of claim 10, wherein the at least one isolation scribe is patterned deep enough to scribe through any one of a contact metal layer, a semiconductor layer, or a transparent conductive oxide layer of the photovoltaic module.

13. The method of claim 10, wherein the at least one isolation scribe is patterned to extend the entire length of the photovoltaic module.

14. The method of claim 10, wherein the at least one isolation scribe is patterned to extend across the at least one columnar cell at locations of the photovoltaic module where a clamp mounts the photovoltaic module to a supporting structure, and wherein the at least one isolation scribe further extends across at least one columnar cell beyond each edge of the clamp.

15. The method of claim 14, wherein the at least one isolation scribe is patterned about 5 inches to about 7 inches in length.

16. The method of claim 10, wherein the at least one isolation scribe is patterned to have a width of about 50 μm.

17. The method of claim 10, further comprising the step of patterning at least a second isolation scribe spaced from and parallel to the at least one isolation scribe, wherein the at least a second isolation scribe is patterned to extend the same length as the at least one isolation scribe and is spaced about 1 mm to about 4 cm therefrom.

18. A photovoltaic module, comprising:
a plurality of columnar photovoltaic cells; and
a plurality of isolation scribes, each isolation scribe extending across at least one photovoltaic cell in a direction perpendicular to a length of the columnar cells and being deep enough to achieve electric isolation between portions of the at least one photovoltaic cell on opposite sides of the respective one of the plurality of isolation scribes,
wherein a first set of the plurality of isolation scribes is located near a first edge of an active area of the photovoltaic module, the isolation scribes of the first set being arranged to be parallel to and spaced about 1 mm to about 4 cm apart from each other, and
wherein a second set of the plurality of isolation scribes is located near a second edge of the active area of the photovoltaic module, the isolation scribes of the second set being arranged to be parallel to and spaced about 1 mm to about 4 cm apart from each other.

19. The photovoltaic module of claim 18, wherein each of the plurality of isolation scribes extends an entire length of the photovoltaic module.

20. The photovoltaic module of claim 18, wherein each of the plurality of isolation scribes extends across the at least one photovoltaic cell at locations of the photovoltaic module where a clamp mounts the photovoltaic module to a supporting structure, and wherein the at least one isolation scribe further extends across at least one photovoltaic cell beyond each edge of the clamp.
